(19) United States
(12) Patent Application Publication
(10) Pub. No.: US 2016/0202489 A1
(43) Pub. Date: Jul. 14, 2016

(54) LIQUID CRYSTAL LENS UNIT AND THREE DIMENSIONAL DISPLAY DEVICE INCLUDING THE SAME

(71) Applicant: SAMSUNG DISPLAY CO., LTD., Yongin-City (KR)

(72) Inventors: Hyun Seung SEO, Anyang-si (KR); Soo Hee OH, Hwaseong-si (KR); Seung Jun JEONG, Hwaseong-si (KR)

(21) Appl. No.: 14/806,911

(22) Filed: Jul. 23, 2015

(30) Foreign Application Priority Data
Jan. 9, 2015 (KR) 10-2015-0003503

(51) Int. Cl. G02B 27/22; H01L 27/32; G02B 3/08; G02F 1/1343; G02F 1/1337

(52) U.S. Cl. CPC G02B 27/22; G02F 1/13439; G02F 1/1337; G02B 3/08; H01L 27/3232

(57) ABSTRACT

A liquid crystal lens unit is provided as follows. Lower plate electrodes are positioned on a first substrate. The lower plate electrodes are extended in a first direction and spaced apart from each other in a second direction crossing the first direction. An upper plate electrode is positioned on the lower plate electrodes. A second substrate is positioned on the upper plate electrode. A liquid crystal layer is positioned between the lower plate electrodes and the upper electrode. A first voltage is applied to at least two outermost lower plate electrodes and then, a second voltage lower than the first voltage is applied to at least two second outermost lower plate electrodes.

### CROSS-REFERENCE TO RELATED APPLICATION

This application claims priority under 35 U.S.C. §119 to Korean Patent Application No. 10-2015-0003503, filed on Jan. 9, 2015 in the Korean Intellectual Property Office, the disclosure of which is incorporated by reference herein in its entirety.

### TECHNICAL FIELD

The present invention relates to a liquid crystal lens unit and a three dimensional (3D) display device.

### DISCUSSION OF RELATED ART

In general, the factors for a person to recognize a 3D effect includes a physiological factor and an experimental factor, and in a 3D image display technique, a 3D effect of an object is recognized, in a short range, by using binocular parallax. A method using the binocular parallax generally includes a method (stereoscopy) to wear spectacles and a non-spectacle method (autostereoscopy) not to wear the spectacles.

In the autostereoscopy, a parallax barrier method and a liquid crystal lens method are used. For the liquid crystal lens method, a liquid crystal lens is formed as a Fresnel lens.

### SUMMARY

According to an exemplary embodiment of the present invention, a liquid crystal lens unit is provided as follows. Lower plate electrodes are positioned on a first substrate. The lower plate electrodes are extended in a first direction and spaced apart from each other in a second direction crossing the first direction. An upper plate electrode is positioned on the lower plate electrodes. A second substrate is positioned on the upper plate electrode. A liquid crystal layer is positioned between the lower plate electrodes and the upper electrode. A first voltage is applied to at least two outermost lower plate electrodes and then, a second voltage lower than the first voltage is applied to at least two second outermost lower plate electrodes.

According to an exemplary embodiment of the present invention, a 3D display device includes a display panel displaying an image and a liquid crystal lens unit. The lens unit includes a first substrate, lower plate electrodes positioned on the first substrate, extended in a first direction on the first substrate and spaced apart from each other in a second direction crossing the first direction, and an upper plate electrode positioned on the lower plate electrodes. The lens unit further includes a second substrate positioned on the upper plate electrode and a liquid crystal layer positioned between the lower plate electrodes and the upper electrode. A first voltage is applied to at least two outermost lower plate electrodes and then, a second voltage lower than the first voltage is applied to at least two second outermost lower plate electrodes.

According to an exemplary embodiment of the present invention, a 3D display device includes a display panel displaying an image, a liquid crystal lens unit displaying the image as a three dimensional image, and a voltage generator. The voltage generator applies sequentially two or more voltages to the liquid crystal lens unit such that the liquid crystal lens performs as a Fresnel lens.

### BRIEF DESCRIPTION OF THE DRAWINGS

These and other features of the present invention will become more apparent by describing in detail exemplary embodiments thereof with reference to the accompanying drawings of which:

FIG. 1 is a cross-sectional view of a 3D display device according to an exemplary embodiment of the present invention;

FIGS. 2A and 2B are plan views of a first substrate and a second substrate of a liquid crystal lens unit of FIG. 1 according to an exemplary embodiment of the present invention;

FIG. 3 is a cross-sectional view of a part of the liquid crystal lens unit of FIG. 1 according to an exemplary embodiment of the present invention;

FIG. 4 shows voltages applied to lower plate electrodes of FIG. 1 according to an exemplary embodiment of the present invention;

FIGS. 5A to 5C are cross-sectional views of motions of liquid crystal molecules of the liquid crystal lens unit of FIG. 1, in response to voltages of FIG. 4, according to an exemplary embodiment of the present invention;

FIG. 6 is a plan view illustrating the motion of the liquid crystal of the liquid crystal lens unit illustrated in FIG. 1, in response to voltages of FIG. 4, according to an exemplary embodiment of the present invention; and

FIG. 7 is a table listing collision/no collision between liquid crystal molecules depending on voltages according to an exemplary embodiment of the present invention.

### DETAILED DESCRIPTION OF EXEMPLARY EMBODIMENTS

Exemplary embodiments of the present invention will be described below in detail with reference to the accompanying drawings. However, the present invention may be embodied in different forms and should not be construed as limited to the embodiments set forth herein. In the drawings, the thickness of layers and regions may be exaggerated for clarity. It will also be understood that when an element is referred to as being “on” another element or substrate, it may be directly on the other element or substrate, or intervening layers may also be present. It will also be understood that when an element is referred to as being “coupled to” or “connected to” another element, it may be directly coupled to or connected to the other element, or intervening elements may also be present. Like reference numerals may refer to the like elements throughout the specification and drawings.

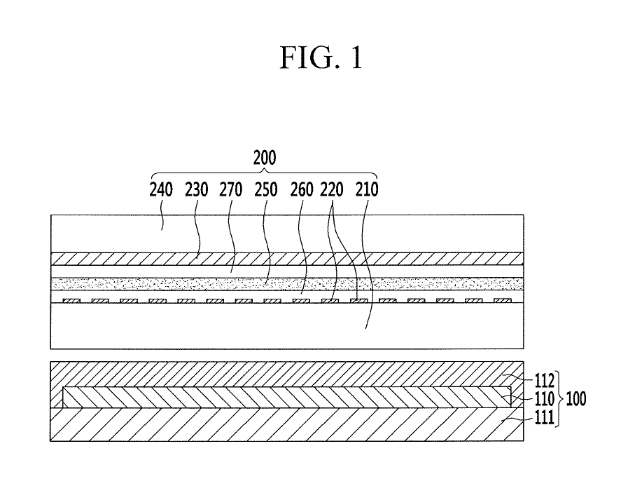

Hereinafter, a 3D display device according to an exemplary embodiment of the present invention will be described with reference to FIGS. 1 to 3.

FIG. 1 is a cross-sectional view illustrating a 3D display device according to an exemplary embodiment of the present invention.

Referring to FIG. 1, the 3D display device includes a display panel 100 and a liquid crystal lens unit 200.

The display panel 100 displays a two dimensional (2D) image, which is a plane image, and may be an organic light emitting diode display (OLED) including an organic light emitting diode or a liquid crystal display device (LCD) including liquid crystal molecules. For the convenience of description, an organic light emitting display device as a display panel 100 will be described as an exemplary embodiment.

The display panel 100 includes both substrates 111 and 112 and a display unit 110 including an organic light emitting diode, which is sealed by both substrates 111 and 112 between both substrates 111 and 112. Herein, both substrates 111 and 112 may be made of glass, plastic, or metal. The display unit 110 may include a circuit unit connected with the organic light emitting diode and the circuit unit may include one or more scan lines, one or more data lines, a plurality of thin film transistors, one or more capacitors, and the like. The circuit unit may be formed in various forms. The display panel 100 may display 2D image using the display unit 110 including the organic light emitting diode.

The display panel 100 may display a left-eye 2D image and a right-eye 2D image in order to cause a user to recognize a 3D image from the 2D images.

At least one of a phase difference plate and a polarizing plate may be attached to a top surface and a bottom surface of the display panel 100. Herein, the polarizing plate may be a linear polarizing plate and the phase difference plate may be a λ/2 phase retardation plate or a λ/4 phase retardation plate.

The liquid crystal lens unit 200 is positioned on the display panel 100. The liquid crystal lens unit 200 includes a first substrate 210, a lower plate electrode 220, an upper plate electrode 230, a second substrate 240, a liquid crystal layer 250, a first alignment layer 260, and a second alignment layer 270.

The lower plate electrode 220, the first alignment layer 260, the liquid crystal layer 250, the second alignment layer 270, the upper plate electrode 230, and the second substrate 240 are sequentially laminated from the first substrate 210.

The lower plate electrode 220 and the first alignment layer 260 are formed on the first substrate 210 and the upper plate electrode 230 and the second alignment layer 270 are formed on the second substrate 240.

The first substrate 210 and the second substrate 240 may be made of transparent glass or plastic.

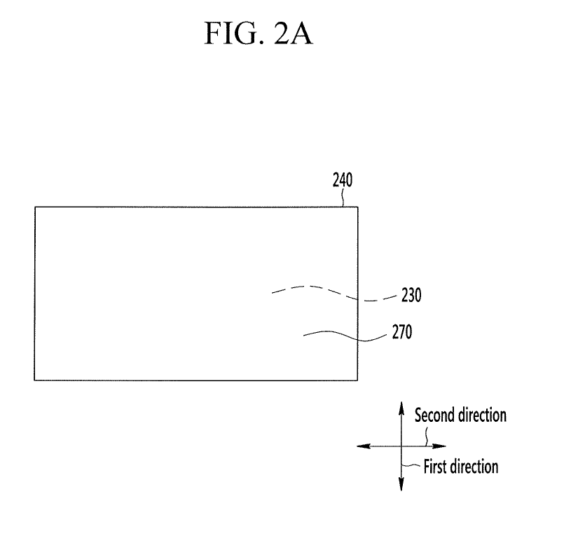

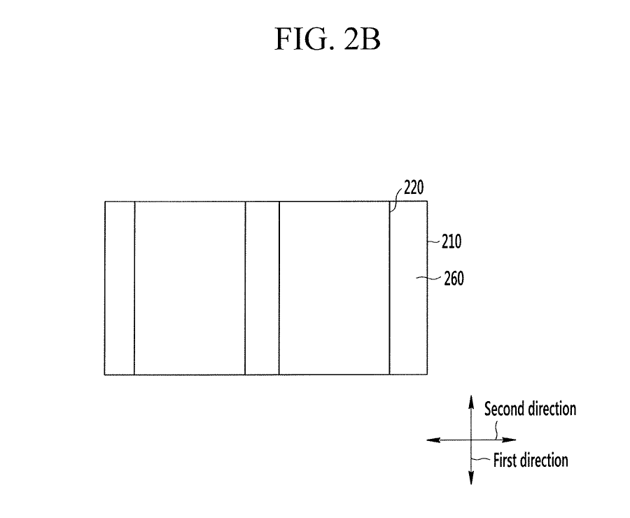

FIGS. 2A and 2B are plan views of a plate surface of a first substrate and a plate surface of a second substrate of FIG. 1. FIG. 2A is a plan view of a part of a plate surface of the second substrate and FIG. 2B is a plan view of a part of a plate surface of the first substrate.

Referring to FIGS. 2B and 1, lower plate electrodes 220 are provided, and each lower plate electrode 220 extends on the plate surface of the first substrate 210 in a first direction. The lower plate electrode are spaced apart from each other in a second direction crossing the first direction. Herein, the first direction and the second direction may be substantially perpendicular to each other, but the present invention is not limited thereto. For example, the first direction and the second direction cross each other at an angle, and the lower plate electrodes may extend at the angle.

The lower plate electrodes 220 are formed on the same layer, but the present invention is not limited thereto. For example, the lower plate electrodes 220 may be formed on different layers.

The first alignment layer 260 is positioned between the lower plate electrode 220 and the liquid crystal layer 250 and may have a first alignment direction which is the same as the first direction. The first alignment direction of the first alignment layer 260 is the same as the first direction, but the present invention is not limited thereto. For example, the first alignment direction may be a direction that crosses the first direction.

Referring to FIGS. 2A and 1, the upper plate electrode 230 is formed of a single plate layer, overlapping the lower plate electrodes 220.

The second alignment layer 270 is positioned between the upper plate electrode 230 and the liquid crystal layer 250. The second alignment layer 270 may have the first alignment direction of the first alignment layer 260. The present invention is not limited thereto. For example, the second alignment layer 270 may have a second alignment direction different from the first alignment direction.

The liquid crystal layer 250 is positioned between the first alignment layer 260 and the second alignment layer 270. The liquid crystals of the liquid crystal layer 250 may be vertically aligned (VA). The liquid crystal molecules of the liquid crystal layer 250 may be tilted by an electric field formed according to a voltage difference applied between the lower plate electrode 220 and the upper plate electrode 230.

The voltage is applied to the plurality of lower plate electrodes 220 and the upper plate electrode 230 so as to recognize the 2D image displayed from the display panel 100 that penetrates the liquid crystal lens unit 200 as the 3D image and in this case, the liquid crystal layer 250 may have a Fresnel lens form.

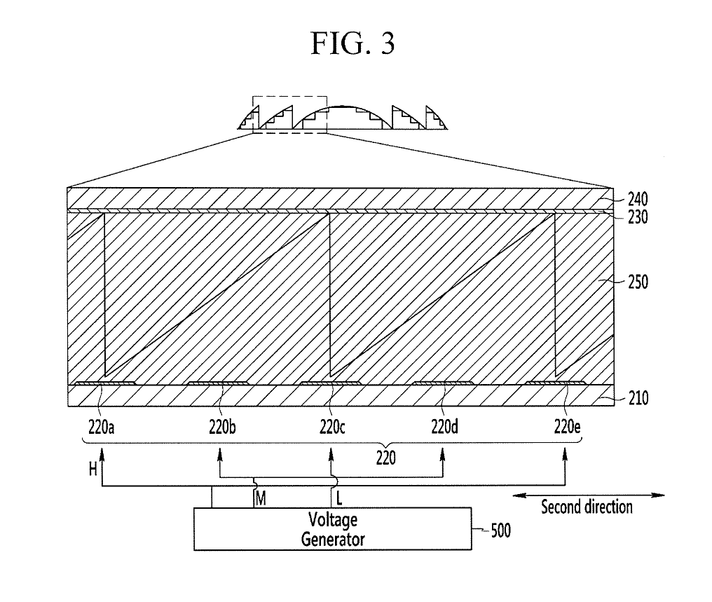

Hereinafter, this will be described with reference to FIG. 3.

FIG. 3 is a cross-sectional view of a part of the liquid crystal lens unit 200 of FIG. 1. The liquid crystal layer 250 of the liquid crystal lens unit 200 may serve as a Fresnel lens form. The part of the liquid crystal lens unit 200 may be a part of a Fresnel lens formed by the entire liquid crystal layer 250.

Referring to FIG. 3, a lower plate electrode 220 includes a first lower plate electrode 220a, a second lower plate electrode 220b, a third lower plate electrode 220c, a fourth lower plate electrode 220d, and a fifth lower plate electrode 220e which are sequentially deployed. Set voltage is applied to each of the upper plate electrode 230 and the plurality of lower plate electrode 220 such that the liquid crystal layer 250 performs as a Fresnel lens. A part of the liquid crystal layer 250 corresponding among the first lower plate electrode 220a, the second lower plate electrode 220b, and the third lower plate electrode 220c may constitute a part of the Fresnel lens. First voltage H is applied to each of the first lower plate electrode 220a and the fifth lower plate electrode 220e, second voltage M is applied to each of the second lower plate electrode 220b and the fourth lower plate electrode 220d, and third voltage L is applied to the third lower plate electrode 220c. Herein, the second voltage M is lower than the first voltage H and the third voltage L is lower than the second voltage M. For example, the first voltage H, the second voltage M, and the third voltage L may decrease in that order.

As a result, the liquid crystal layer 250 forms a Fresnel lens and the 2D image displayed from the display panel 100 is viewed as a 3D image by the Fresnel lens.

As one example, when the liquid crystal layer 250 has the Fresnel lens form in order to recognize the 3D image, the display panel 100 displays N viewpoint images in n (n is a natural number) continued pixels, respectively. N respective viewpoint images are incident in the liquid crystal lens unit 200. N viewpoint images are refracted to n viewpoint areas by the liquid crystal lens unit 200 including the liquid crystal layer 250 having the Fresnel lens form to be recognized as the 3D image.

The first voltage H, the second voltage M, and the third voltage L are sequentially applied to the first lower plate electrode 220a and the fifth lower plate electrode 220e, the second lower plate electrode 220b and the fourth lower plate electrode 220d, and the third lower plate electrode 220c, respectively, and as a result, the refraction of the light penetrating the liquid crystal lens unit 200 is prevented from being distorted.

For example, the first voltage H is applied to the first lower plate electrode 220a and the fifth lower plate electrode 220e which are the lower plate electrodes spaced apart from each other with the second lower plate electrode 220b, the third lower plate electrode 220c, and the fourth lower plate electrode 220d which are one or more lower plate electrodes among the lower plate electrodes 220 interposed therebetween and then, the second voltage M lower than the first voltage H is applied to the second lower plate electrode 220b and the fourth lower plate electrode 220d which are one or more lower plate electrodes and then, the third voltage L lower than the second voltage M is applied to the third lower plate electrode 220c. As a result, the liquid crystal molecules of the liquid crystal layer 250 corresponding to the first lower plate electrode having the first voltage H higher than other voltage are tilted without interfering neighboring liquid crystal molecules.

The first and fifth lower plate electrodes 220a and 220e is outermost lower plate electrodes. The second and fourth lower plate electrodes 220b and 220d is second outermost lower plate electrodes.

In FIG. 3, the liquid crystal lens unit 200 of FIG. 1 is electrically coupled to a voltage generator 500. The voltage generator 500 applies sequentially a plurality of voltages to the liquid crystal lens unit 200. For example, the voltage generator 500 applies sequentially the first voltage H, the second voltage M and the third voltage L to the outermost electrodes 220a and 220e, and the second outermost electrodes 220b and 220d, and an innermost electrode 220c, respectively. For the convenience of description, it is assumed that the liquid crystal lens unit 200 include five electrodes 220a to 220e and three voltages H, M and L. However, the present invention is not limited thereto. For example, the number of lower plate electrodes may be greater or smaller than five, and the number of voltages applied from the voltage generator may be greater or smaller than three.

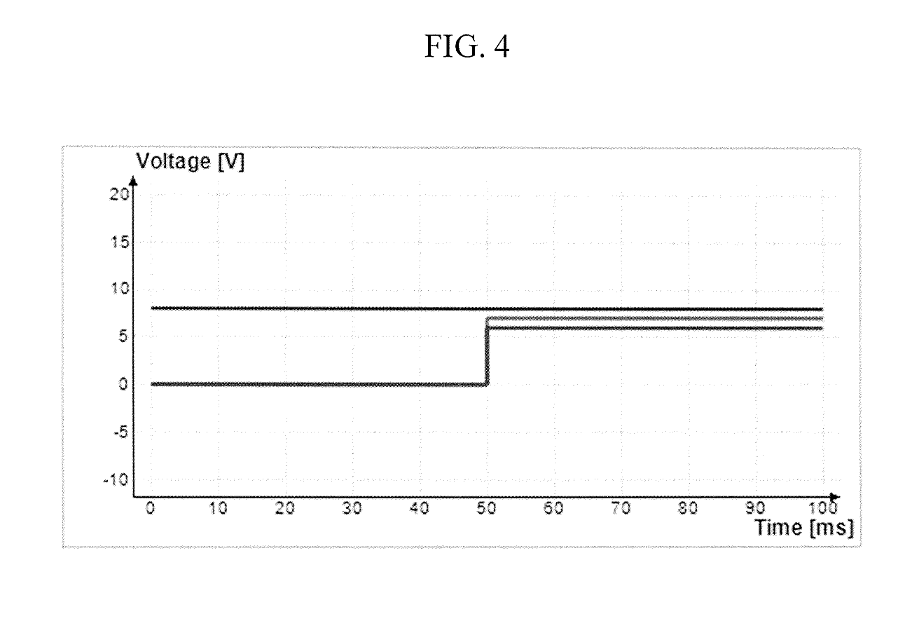

Such an effect will be described below with reference to FIGS. 4 to 6.

Disclination (DS) of the liquid crystal molecules occurs by interference among the neighboring liquid crystal molecules in the liquid crystal layer 250 on the border of the lenses corresponding between lower plate electrodes 220 when different voltages are applied to adjacent lower plate electrodes 220. When the disclination (DS) occurs in the liquid crystal layer 250 formed on the border of the lenses, and since the refraction of the light penetrating the liquid crystal layer 250 is distorted on the border of the lenses, display quality of the 3D image implemented by the liquid crystal lens unit 200 deteriorates. In an exemplary embodiment, such distortion may be eliminated or minimized by applying sequentially voltages to the lower plate electrodes 220.

FIG. 4 shows voltages applied with time to lower plate electrodes of the liquid crystal lens unit of FIG. 1.

Referring to FIG. 4, the first voltage H is applied to the first lower plate electrode 220a and the fifth lower plate electrode 220e between 0 ms and 50 ms while a common voltage is applied to the upper plate electrode. The second voltage M is, then, applied to the second lower plate electrode 220b and the fourth lower plate electrode 220d between 50 ms and 100 ms and the third voltage L is applied to the third lower plate electrode 220c at the same time. The present invention is not limited thereto. For example, the third voltage L may be applied after the application of the second voltage M.

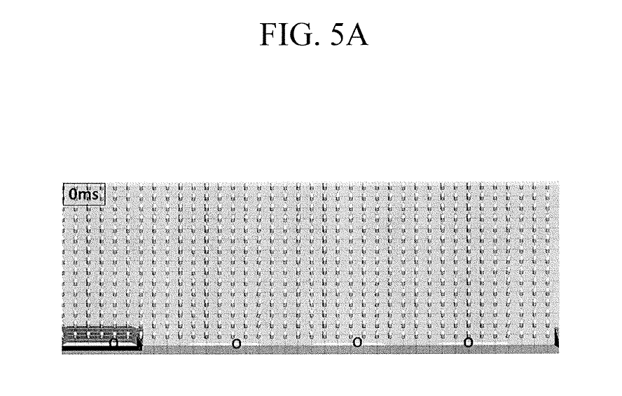

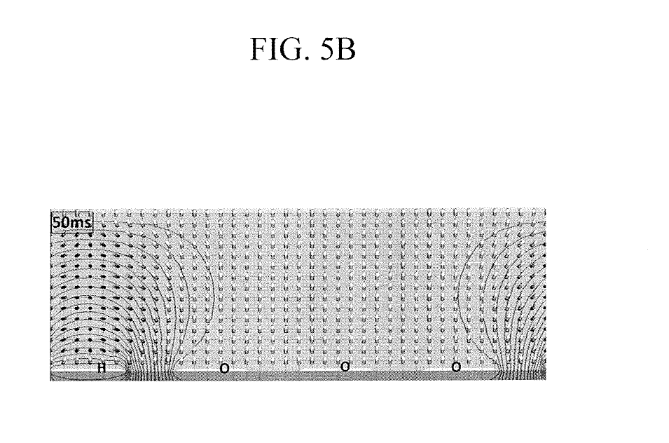

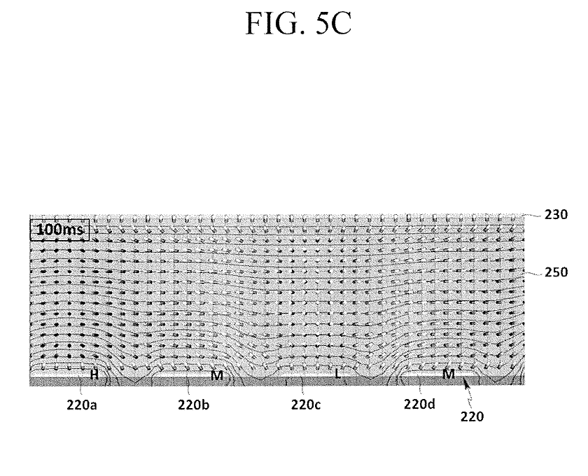

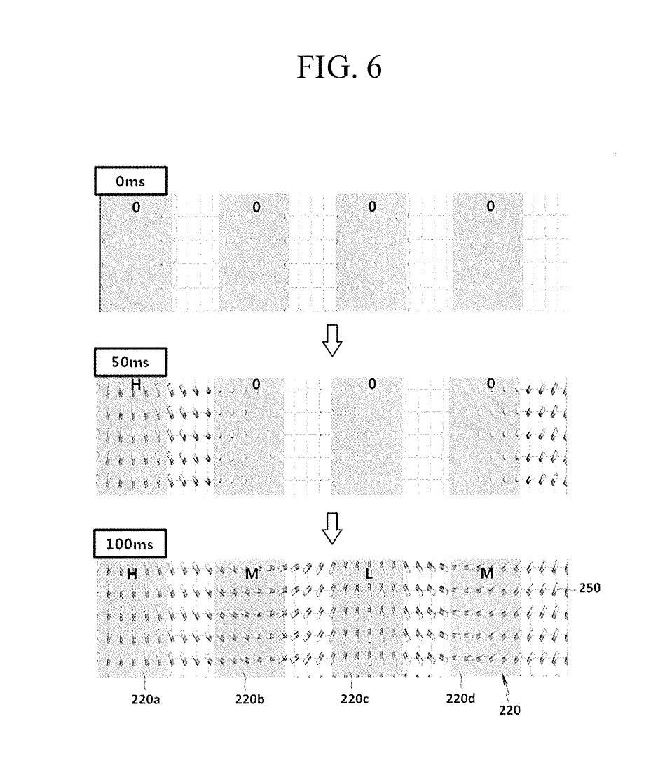

FIGS. 5A to 5C are cross-sectional view of motions of liquid crystal molecules of the liquid crystal lens unit of FIG. 1, in response to the voltages of FIG. 4. FIG. 6 is a plan view illustrating the motion of the liquid crystal molecules of the liquid crystal lens unit of FIG. 1, in response to the voltage of FIG. 4, according to an exemplary embodiment of the present invention.

Referring to FIGS. 5A to 5C and FIG. 6, the liquid crystal molecules of the liquid crystal layer 250 disposed between the first lower plate electrode 220a and the upper plate electrode and between the fifth lower plate electrode 220e and the upper plate electrode 230 are first tilted by an electric field formed between the first lower plate electrode 220a and the upper plate electrode 230 and between the fifth lower plate electrode 220e and the upper plate electrode 230. The electric field is formed by a voltage difference between the first voltage H and the common voltage, and is formed between 0 milliseconds (ms) and 50 ms.

Next, the liquid crystal molecules of the liquid crystal layer 250 disposed between the second lower plate electrode 220b, the fourth lower plate electrode 220d, and the third lower plate electrode 220c and the upper plate electrode 230 are tilted by electric fields formed by voltage differences between each of the second lower plate electrode 220b, the fourth lower plate electrode 220d, and the third lower plate electrode 220c and the upper plate electrode 230. A first voltage difference is formed between the second voltage M and the common voltage. A second voltage difference is formed between the third voltage L and the common voltage. The electric fields are applied to the liquid crystal molecules disposed between the upper plate electrode 230 and the second to fourth lower plate electrodes between 50 ms and 100 ms.

As described above, the liquid crystal molecules of the liquid crystal layer 250 corresponding to the first lower plate electrode 220a are first tilted, and as a result, the interference among the liquid crystal molecules is prevented in the liquid crystal layer 250 formed on the border between the first lower plate electrode 220a and the second lower plate electrode 220b to which the higher voltage than other lower plate electrodes.

For example, the first voltage H is applied to the first lower plate electrode 220a and the fifth lower plate electrode 220e which are the lower plate electrodes spaced apart from each other with the second lower plate electrode 220b, the third lower plate electrode 220c, and the fourth lower plate electrode 220d which are one or more lower plate electrodes among the lower plate electrodes 220 interposed therebetween and thereafter, the second voltage M lower than the first voltage H is applied to the second lower plate electrode 220b and the fourth lower plate electrode 220d which are one or more lower plate electrodes and the third voltage L lower than the second voltage M is applied to the third lower plate electrode 220c, and as a result, the liquid crystal molecules of the liquid crystal layer 250 disposed between the first lower plate electrode having the first voltage H higher than other voltages are first tilted without being interfered by neighboring liquid crystal molecules of the liquid crystal layer 250.

In an exemplary embodiment, the refraction of the light penetrating the liquid crystal lens unit 200 is prevented from being distorted, and thus the display quality of the 3D image using the liquid crystal lens unit is increased.

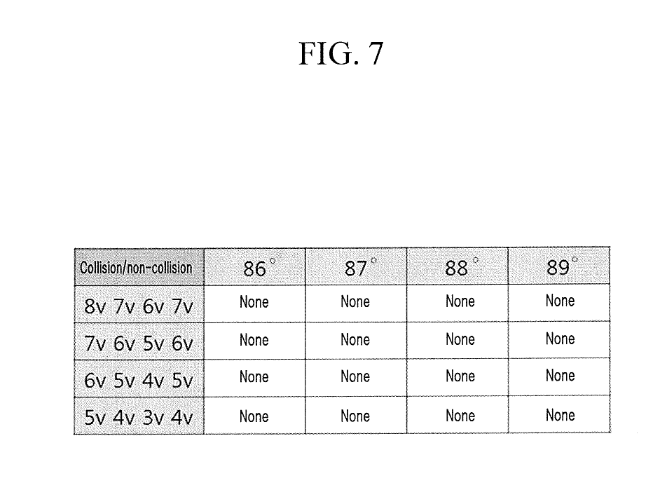

Hereinafter, an experimental example of verifying the effect of the present invention will be described with reference to FIG. 7.

FIG. 7 is a table listing the experimental example of the liquid crystal lens unit illustrated in FIG. 1.

Referring to FIG. 7, 8 V is applied to the first lower plate electrode when the vertical alignments of the liquid crystal molecules of the liquid crystal layer are set to 86°, 87°, 88°, and 89°, respectively. Thereafter, 7 V, 6 V, and 7 V are applied to the second lower plate electrode, the third lower plate electrode, and fourth lower plate electrode, respectively. In this case, there is no collide among liquid crystal molecules positioned between the first lower plate electrode and the second lower plate electrode.

While the present invention has been shown and described with reference to exemplary embodiments thereof, it will be apparent to those of ordinary skill in the art that various changes in form and detail may be made therein without departing from the spirit and scope of the present invention as defined by the following claims.

What is claimed is:

1. A liquid crystal lens unit comprising:
a first substrate;
a plurality of lower plate electrodes positioned on the first substrate, wherein the lower plate electrodes are extended in a first direction and spaced apart from each other in a second direction crossing the first direction;
an upper plate electrode positioned on the lower plate electrodes;
a second substrate positioned on the upper plate electrode;
a liquid crystal layer positioned between the lower plate electrodes and the upper electrode,
wherein a first voltage is applied to at least two outermost lower plate electrodes and then, a second voltage lower than the first voltage is applied to at least two second outermost lower plate electrodes.

2. The liquid crystal lens unit of claim 1, wherein liquid crystal molecules of the liquid crystal layer are vertically aligned (VA).

3. The liquid crystal lens unit of claim 2, further comprising:
a first alignment layer positioned between the lower plate electrodes and the liquid crystal layer and having a first alignment direction which is substantially the same as the first direction.

4. The liquid crystal lens unit of claim 3, further comprising:
a second alignment layer positioned between the upper plate electrode and the liquid crystal layer and having the first alignment direction.

5. The liquid crystal lens unit of claim 1, wherein the lower plate electrodes include at least five electrodes arranged in the second direction and in the order of a first lower plate electrode, a second lower plate electrode, a third lower plate electrode, a fourth lower plate electrode and a fifth lower plate electrode, and wherein the first voltage is applied to the first lower plate electrode and the fifth lower plate electrode of at two outermost lower plate electrodes.

6. The liquid crystal lens unit of claim 5, wherein the second voltage is applied to the second lower plate electrode and the fourth lower plate electrode of at least two second outermost lower plate electrodes, and a third voltage lower than the second voltage is applied to the third lower plate electrode interposed between the second and fourth lower plate electrodes.

7. The liquid crystal lens unit of claim 1, wherein the liquid crystal layer performs, in response to an electric field formed between the lower plate electrodes and the upper plate electrode, as a Fresnel lens.

8. A 3D display device comprising:
a display panel displaying an image; and
a liquid crystal lens unit including:
a first substrate;
a plurality of lower plate electrodes positioned on the first substrate, extended in a first direction on the first substrate and spaced apart from each other in a second direction crossing the first direction;
an upper plate electrode positioned on the lower plate electrodes;
a second substrate positioned on the upper plate electrode; and
a liquid crystal layer positioned between the lower plate electrodes and the upper electrode,
wherein a first voltage is applied to at least two outermost lower plate electrodes and then, a second voltage lower than the first voltage is applied to at least two second outermost lower plate electrodes.

9. The 3D display device of claim 8, wherein:
the lower plate electrodes include at least five electrodes arranged in the second direction and in the order of a first lower plate electrode, a second lower plate electrode, a third lower plate electrode, a fourth lower plate electrode, and a fifth lower plate electrode, and
the first voltage is applied to of the first lower plate electrode and the fifth lower plate electrode of at least two outermost electrodes.

10. The 3D display device of claim 9, wherein:
the second voltage is applied to the second lower plate electrode and the fourth lower plate electrode of at least two second outermost electrodes, and a third voltage lower than the second voltage is applied to the third lower plate electrode disposed between the second and fourth electrodes.

11. The 3D display device of claim 8, wherein:
the liquid crystal layer performs, in response to an electric field formed between the lower plate electrodes and the upper plate electrode, as a Fresnel lens.

12. The 3D display device of claim 8, wherein the display panel includes an organic light emitting diode.

13. A 3D display device comprising:
a display panel displaying an image;
a liquid crystal lens unit configured to display the image as a three dimensional image;
a voltage generator configured to apply sequentially two or more voltages to the liquid crystal lens unit such that the liquid crystal lens performs as a Fresnel lens.

14. The 3D display device of claim 13, wherein the liquid crystal lens unit including:
at least five plate electrodes spaced apart from each other;
an upper plate electrode facing the lower plate electrodes;
a liquid crystal layer positioned between the lower plate electrodes and the upper electrode,
wherein at least two outermost lower plate electrodes are applied with a first voltage from the voltage generator and then, at least two second outermost lower plate electrodes are applied with a second voltage.

15. The 3D display device of claim 14, wherein at least third outermost lower plate electrodes are applied with a third voltage from the voltage generator, wherein the second and third voltages are applied at substantially the same time.
